(19) United States
(12) Patent Application Publication
(10) Pub. No.: US 2005/0179442 A1
(43) Pub. Date: Aug. 18, 2005

(54) Device for testing cables provided with luminous signals

(76) Inventor: Bruno Coissac, Asnieres/ Seine (FR)

Correspondence Address: Bruno Coissac, 258 Avenue D'Argenteuil, Asnieres Sur Seine, 92600, FR

(21) Appl. No.: 10/515,578

(22) PCT Filed: May 21, 2003
(86) PCT No.: PCT/FR03/01527

(30) Foreign Application Priority Data
May 30, 2002 (FR) 02/06646

(51) Int. Cl. H04B 3/46; G01R 31/02

(52) U.S. Cl. 324/542

(57) ABSTRACT

The invention relates to a portable device for testing and analysing cables provided with connectors. According to the invention, said device permits a rapid manipulation and analytical reading whatever the light environment and comprises connector sockets (ED, EA), luminous elements (D) of wich the intensity is at least one thousand millicandelas, arranged and organised on the surface thereof in groups of two (G2), three (G3) or four (G4). Said device is particularly for application in the audiovisual field.

This invention concerns a portable and self-contained device for quickly testing and analysing cables fitted with connectors, whatever the light environment.

To transport professional audio modulation and amplitude signals, many possible combinations of different connectors can be mounted on the same cable, as well as cables with a male connector on one end and a female connector on the other.

In addition, for a given combination of different or similar connectors, there are several possibilities of connecting their contact pins or terminals.

Also, it is frequent to come across the connection of a pin or point towards 2 pins or points, representing a short-circuit which may be desirable in some cases, and not at all in others.

Connector cables used for transporting data for slaved projectors and some spectacle machines under remote control are often used on the same operating sites as audio signal transport cables.

Without going into electrical power supply, the effective number of cables with professional audio and lighting connectors is also increased by a “safety” quantity to cover the possibility of being unable to analyse each of them rapidly when preparing the equipment.

In most of the companies working in the field of equipment rental and service provisions, connector cables are manufactured in-house and at this stage, checked only by a continuity tester or by a beeper incorporated into the probe-type voltmeter.

Each of these two beeper probes is applied to one end of the cable, a slow operation because the probes have to be moved to each pin or point while maintaining the connectors and, if the combinations are not straight, call for a great deal of attention and memory. Then, the cables are used until frequent manipulation of them causes problems to occur.

There are a test systems for these cables but none of them covers the main connectors used for audio signal transport and data transmission for projectors slaved onto the single portable device that can be manipulated quickly for reading, easy and fast analysis of all the possible combinations of contact pins and points in various light environments with changing intensity and lighting.

The device according to the invention enables the user to:
test by a fast and easy manipulation all of the cables equipped with the connectors most widely used worldwide for transporting audio signals and data transmissions for slaved projectors, their accessories and some spectacle machines featuring remote control.
quickly analyse all the possible combinations between these connectors and between their pins and contact points to quickly carry out, without any error, the desired connections between the various equipment and selecting the connector cables whose contact pins and points are connected suitably.
obtaining easy and fast analysis and reading whatever the light environment, dark, high-intensity or changing, as often occurs on a live spectacle site or installation location.

The device according to the invention combines these functions in a compact, portable, self-contained device capable of resisting the physical and thermal shocks most often encountered in professional use.

By international convention, the contact pins and points of the chosen connector sockets are numbered and designated as follows:
XLR 5-pin: 1, 2, 3, 4, 5.
XLR 3-pin: 1, 2, 3
SPEAKON 4-point: −1, +1, −2, +2.
JACK 3-point: SLEEVE, TIP, RING
JACK 2-point: SLEEVE, TIP
CINCH/RCA: 2-points: SLEEVE, TIP

List and number of chosen connector sockets:
XLR 5-pin male ×1
XLR 5-point female ×1
XLR 3-pin male ×1
XLR 3-point female ×1
SPEAKON 4-point female ×2
JACK 3-point female ×2
JACK 2-point female ×2
RCA 2-point female ×2

This list, corresponding to the cables with connectors most often used in the world of sound and light can be modified in part or in an extended manner to accommodate the 5-pin 180° DIN product used for the MIDI standard (data transmission for musical instruments) and any other connector with several pins or points, to address the changing market or demand.

This list can be modified entirely or for the application of the device according to the invention in other areas than those of sound and light.

The choice of connector sockets will preferably go to models not including a system for retaining the connectors of the cables to be tested so as to facilitate fast handling, particularly for the XLR and JACK connectors.

This choice will preferably be made from the ranges of leading makers, especially for the XLR and SPEAKON products, to guarantee longevity and compatibility.

According to particular embodiments, on the facade of the device according to the invention, the connector sockets will be set out in two zones, one containing the so-called output sockets and the other the so-called input sockets.

For ease of reading, it is preferable to place the 3-pin male XLR socket in the output area, in particular for combinations between three-pin XLR and SPEAKON.

Many audio amplifiers have speaker outputs equipped with male three-pin XLR plugs and many speakers have an input equipped with a female SPEAKON device. Some of the output of these amplifiers are connected to pins 1 and 2 of their 3-PIN XLR connector, and others to pins 1 and 3. Some speaker inputs are connected to the contact points −1 and +1 of their SPEAKON connectors and others to the contact points −2 and +2. To connect these amplifiers to these speakers, it is necessary to have female 3-pin XLR connectors on one end and male SPEAKON connectors at the other. The device according to the invention allows them to be selected quickly.

Depending on particular embodiments, the most practical distribution between the so-called output area and the so-called input area for the chosen connector sockets is:
so-called output connector sockets:

XLR 5-pin male, XLR 3-pin male, SPEAKON 4-point female, JACK 3-point female, JACK 2-point female, RCA 2-point female.
so-called input connector sockets:

XLR 5-point female, XLR 3-point female, SPEAKON 4-point female, JACK 3-point female, JACK 2-point female, RCA 2-point female.

According to particular embodiments:
the contact pins and points of the so-called output connector sockets are organized and connected together by electrical contact, cables and/or printed circuit tracks to form 5 different groups each connected by electrical contact, cables and/or tracks to a normally-closed pressure pusle switch. These switches conduct electrical voltage to each of these groups of contact pins and points on the so-called output connector sockets and therefore, through the cable to be analyzed when it is connected.

Group 1 consists of pin 1 of the XLR 5-pin male, pin 1 of the XLR 3-pin male, contact point −1 of the SPEAKON, the SLEEVE point of the 3-point JACK, the SLEEVE point of the 2-point JACK, the RCA SLEEVE point, and is connected to switch 1.

Group 2 consists of pin 2 of the XLR 5-pin male, pin 2 of the 3-pin male XLR, contact point +1 of the SPEAKON, the TIP point of the 3-point JACK, the TIP point of the 2-point JACK, the TIP point of the RCA and is connected to switch 2.

Group 3 consists of pin 3 of the XLR 5-pin male, pin 3 of the 3-pin male XLR, point −2 of the SPEAKON, the RING point of the 3-point JACK, and is connected to switch 3.

Group 4 consists of pin 4 of the XLR 5-pin male, point +2 of the SPEAKON and is connected to switch 4.

Group 5 consists of pin 5 of the XLR 5-pin male and is connected to switch 5.
the contact pins and points of the so-called input sockets are organized and connected together by electric contacts, cables and/or printed circuit tracks so as to form 9 separate groups each connected by electrical contacts, cables and and/or tracks to a high power and low consumption light emitting diode, visible even at high lighting intensity, for instance a red 5,000 milli-candela transparent LED.
Group 1 consists of point 1 of the 5-point female XLR, point 1 of the 3-point female XLR, the SLEEVE point of the 3-point JACK, the sleeve point of the 2-point JACK, the RCA SLEEVE point and is connected to light-emitting diode 1.
Group 2 consists of point 2 of the 5-point female XLR, point 2 of the 3-point female XLR, the TIP point of the 3-point JACK, the TIP point of the 2-point JACK, the RCA TIP point, and is connected to LED 2.
Group 3 consists of point 3 of the 5-point female XLR, point 3 of the 3-point female XLR, the RING point of the 3-point JACK, and is connected to LED 3.
Group 4 consists of point 4 of the 5-point female XLR, and is connected to LED 4.
Group 5 consists of point 5 of the 5-point female XLR, and is connected to LED 5.
Group 6 consists of point −1 of the SPEAKON and is connected to LED 6.
Group 7 consists of point +1 of the SPEAKON and is connected to LED 7.
Group 8 consists of point −2 of the SPEAKON and is connected to LED 8.
Group 9 consists of point +2 of the SPEAKON and is connected to LED 9.

This organization corresponds to a logic that is easy to assimilate by audio and light technicians. For instance, they know that in the case of a straight connection between a 3-pin XLR and a 3-point JACK connector, pin 1 must be connected to a SLEEVE and pin 2 to a TIP and pin 3 to a RING.

When other combinations are desired between these pins and points, it is to address defined functions and equipment needs.

It is easy for the professional to remember that on the so-called output sockets:
pins 1 of XLR and the JACK SLEEVE, RCA SLEEVE and SPEAKON −1 points can be interrogated by switch 1,
pins 2 of XLR and the JACK TIP points, RCA TIP and SPEAKON +1 points can be interrogated by switch 2.
pins 3 of XLR and the JACK RING and SPEAKON −2 points can be interrogated by switch 3.
pin 4 of XLR and SPEAKON point +2 can be interrogated by switch 4.
pin 5 of XLR can be interrogated by switch 5.

A manual indicating this principle can be attached with the device according to the invention or screen-printed on the back of its case.

When the connector cable to be analyzed connects a so-called output connector socket to a so-called input connector socket, the electric voltage conducted through it, by a normally-closed pressure pulse switch, applies power to one or several light-emitting diodes depending on the connection of the contact pins and points of this connector cable.

The device according to the invention may include as means of interrogation by the user, one or several normally-closed pressure pulse switches.

According to particular embodiments:
to allow analysis reading whatever the light environment the device according to the invention may include as light emitting analysis reading resource luminous elements whose luminous intensity is at least one thousand milli candelas for electrical consumption of less than 25 milliamperes.
To allow fast analysis reading the device according to the invention may include luminous elements arranged and organized on the surface to form distinctly separate groups of two, three or four.
these luminous elements can consist of light-emitting diodes.
LEDs 1, 2, 3, 4 and 5 can be arranged on the surface of the device to form a line but a larger space must be allowed between LEDs 3 and 4 than between LEDs 1, 2 and 3 and that between LEDs 4 and 5. In this way, on the same line, two distinctly separate groups will have been arranged. A choice can also be made to form this separation into two groups, not between LEDs 3 and 4, but between LEDs 2 and 3.
LEDs 1, 2, 3, 4 and 5 can also be arranged at the surface of the device to form two lines.
whatever the arrangement chosen, be sure not to arrange the LEDs in distinctly separate groups containing more than four LEDs; beyond that, the user would need more time to count and identify the lighted LED.

According to particular embodiments, these layout principles also apply to LEDs 6, 7, 8 and 9 which, for the sake of speedy analysis reading, can be attributed to the so-called input SPEAKON female 4 point connector and placed near this socket.

These principles of arrangement by groups make it possible to attribute to each luminous element a contact pin or point reference and to memorize them easily by dispensing totally with screen printing on the surface of the device.

Operating Instructions

After plugging the connector at one end of the connector cable into a so-called output socket, and the connector at the other end of the connector cable into a so-called input socket, it is simply necessary to operate the switches, one by one, to read on the luminous elements, the way the contact pins or points are connected from one connector to another on the cable to be analyzed.

To analyze a “Y” cable, it is simply necessary to connect the arms of the “Y” one after the other. To analyze an XLR female-female or male-male connector cable, it is simply necessary to connect to one end an XLR male-male or female-female cable, as applicable, whose pins are connected from one connector to the other in such a way as to correspond.

According to an alternative, the device can include, as analysis reading resource, luminous elements that can comprise segments and/or dots controlled by a microcontroller and on which figures and signs appear designating the contact pins and points of the so-called input connector sockets. The arrangement may designate contact pins and points on the so-called output connector sockets.

According to an alternative, the device can include, as analysis reading resource, luminous elements or displays that can comprise segments and/or dots controlled by a microcontroller and on which figures and signs appear designating the contact pins and points of the so-called input and output connector sockets.

According to these alternatives, the device may include as user interrogation means only one switch, or even none. In the latter case, interrogation takes place by simply connecting the cable to be analyzed to the so-called input and output connector sockets.

According to particular embodiments, in order to enable the device to resist the thermal and physical shocks often encountered in professional situations, it is possible to choose the design of electrical links between internal components (resistors, electric voltage regulators, capacitors, microcontrollers) and surface components (connector sockets, switches, luminous elements or displays), with sheathed flexible cables without a printed circuit board.

But for fast industrial production of the device, it is preferable to design a printed circuit supporting board and the components needed. This board is connected to surface components in the same way as the lighted elements. Steps will be taken to make the printed circuit board and the components integral with the package containing the device, by one or several attaching resources including at least one flexible part between their ends.

Accordingly, the physical shocks that could be caused by falls and thermal variations that could cause the dilatation of the package will be damped by these attaching devices and not absorbed by the supporting board.

To allow easy manipulation and fast access to the normally-closed pressure pulse switches, the surface components of the device can be arranged in such a way that there are no surface components located between the normally-closed pressure pulse switch or switches and any of the edges of the package containing the device.

According to particular embodiments, the device can be housed in a closed package consisting of two plates of sheet metal each bent once so as to be suitable for assembly. These two plates can be a straight along their length and rounded at the ends on at least one of them, then bent once each in their center by cirle arc so that the rounded end of a plate is enclosed as closely as possible by the circle arc fold of the second plate when they are assembled.

The attached drawings illustrate the invention:

FIG. 1 represents an organizational view of the surface components according to one version of the device.

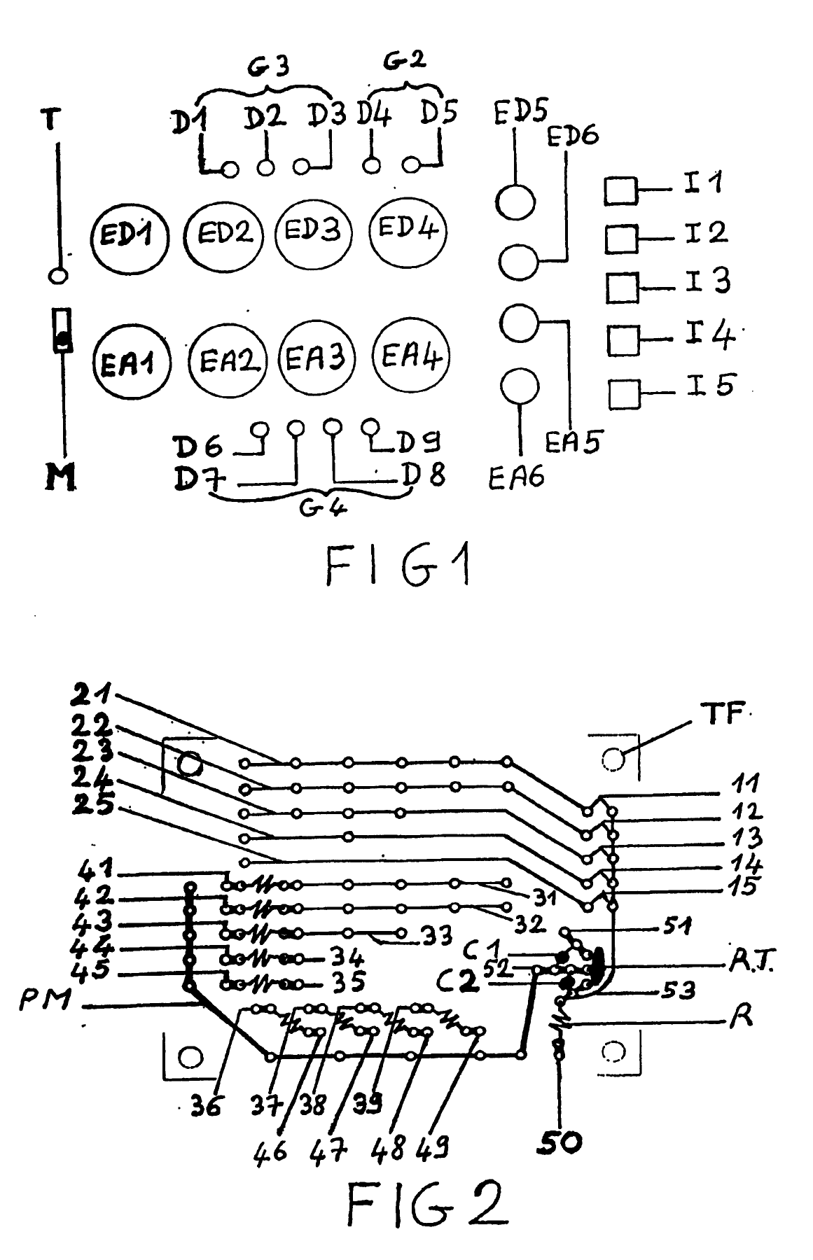

FIG. 2 represents, according to the same version the layout of the internal components and the links for the surface-mounted components on a supporting board; the printed circuit board is visible transparently, back to front.

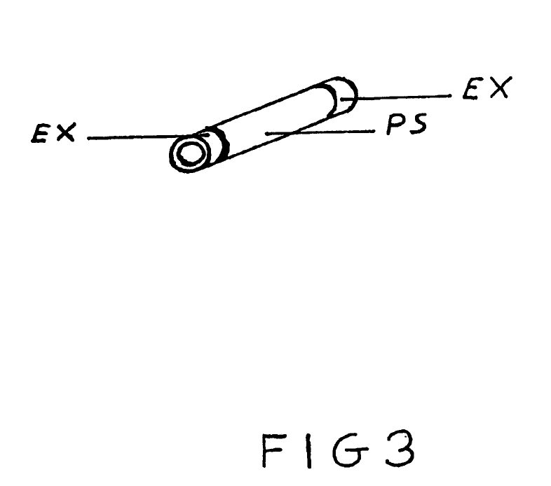

FIG. 3 shows a means of attachment for the component and circuit supporting board.

By reference to these drawings, the device includes:
a printed circuit board and the components to which a positive electric voltage regulator (RT) is soldered, supplying an output voltage of 5 volts. This regulator (RT) has an input stabilized by a capacitor (C1) having a value of 0.33 microfarad and an output stabilized by a capacitor (C2) rated at 0.1 micro farad. This regulator (RT) can be powered by a 9 V battery with the negative terminal connected by a flexible conductor, sheathed and soldered to a contact ring (52) forming a ground track (PM). The positive terminal of the battery is connected by a flexible, sheathed and soldered conductor to one of the contacts of a single pole power switch (M). The other contact of the switch (M) is connected by a flexible, sheathed and soldered conductor to a contact ring (51) on a printed circuit track. This track conducts as far as the input of the voltage regulator (RT).

The output of the regulator (RT) feeds power to a track (53) on the printed circuit and through a flexible and sheathed conductor cable feeds power to a contact ring (50), the anode of a conventional green light emitting diode (T) denoting the energizing and charging of the battery. The current of this diode is limited to approximately 11 milliamperes by a resistor (R) having a value of approximately 460 ohms.
a normally-closed pressure pulse single-pole switch (11) connected by two flexible conducting cables, sheathed and soldered to two contact rings (11) provide an electrical link between the output track (53) of the regulator (RT) and a printed circuit track (21).
a normally-closed contact pressure pulse single-pole switch (12) connected by two flexible, sheathed conducting cables to two contact rings (12) permit an electrical link between the output track (53) of regulator (RT) and a printed circuit track (22).
a normally-closed contact pressure pulse single-pole switch (13) connected by two flexible, sheathed conducting cables to two contact rings (13) permit an electrical link between the output track (53) of regulator (RT) and a printed circuit track (23).
a normally-closed contact pressure pulse single-pole switch (14) connected by two flexible, sheathed conducting cables to two contact rings (14) permit an electrical link between the output track (53) of regulator (RT) and a printed circuit track (24).
a normally-closed contact pressure pulse single-pole switch (15) connected by two flexible, sheathed conducting cables to two contact rings (15) permit an electrical link between the output track (53) of regulator (RT) and a printed circuit track (25).
so-called output connector sockets (ED) arranged and attached to the surface of the package accommodating the device can be described as follows: XLR 5 pin male (ED1), XLR 3 pin male (ED2), SPEAKON 4 point female (ED3), JACK 3 point female (ED4), RCA 2 point female (ED5) and JACK 2 point female (ED6). The contact pins and points of these connector sockets are connected to their printed circuit tracks as follows: Pin 1 of XLR 5 male, pin 1 of XLR 3 male, point −1 of SPEAKON female, SLEEVE point of 3-point female JACK, RCA female SLEEVE point, and
SLEEVE point of female 2-point JACK are each connected by a flexible sheathed conductor soldered to a ring on their track (21); pin 2 of male XLR 5, pin 2 of male XLR 3, point +1 of female SPEAKON, TIP of 3-point female JACK, female RCA TIP and TIP point of 2-point female JACK are each connected by a flexible sheathed cable soldered to a contact ring on their track (22); pin 3 of male XLR 5, pin 3 of XLR 3 male, point −2 of female SPEAKON and RING of 3-point female JACK each connected by a flexible conductor cable sheathed and soldered, to a contact ring on their track (23); pin 4 of male XLR 5 and point +2 of female SPEAKON each being connected by a flexible conductor cable, sheathed and soldered to a contact ring on their track (24); pin 5 of male XLR 5 is connected by a conducting flexible conductor, sheathed and soldered to a contact ring on its track (25).
so-called input connector sockets (EA) arranged and attached to the surface of the package hosting the device that can be described as follows: XLR 5 point female (EA1), XLR 3 point female (EA2), SPEAKON 4 point female (EA3), JACK 3 point female (EA4), RCA 2 point female (EA5) et JACK 2-point female (EA6).

The contact points of these connector sockets are connected to their printed circuit tracks as follows: point 1 of XLR 5 female, point 1 of XLR 3 female, SLEEVE point of 3-point female JACK, SLEEVE point of female RCA and SLEEVE point of 2-point female JACK are each connected by a flexible, sheathed conductor soldered to a contact ring on their track (31); point 2 of female XLR 5, point 2 of XLR 3 female, TIP point of 3-point female JACK, TIP point of female RCA and TIP point of 2-point female JACK are each connected by a flexible sheathed conductor cable soldered to a contact ring on their track (32); point 3 of female XLR 5, point 3 of female XLR 3 and RING point of 3-point female JACK are each connected by a flexible conductor cable soldered to a contact ring on their track (33); point 4 of female XLR 5 is connected by a flexible sheathed conductor soldered to a contact ring (34); point 5 of female XLR 5 is connected by a flexible, sheathed conductor soldered to a contact ring (35); point −1 of the female 4-point SPEAKON being connected by a flexible sheathed conductor cable to a contact ring (36); point +1 of the 4-point female SPEAKON is connected by a flexible, sheathed conductor cable soldered to a contact ring (37); point −2 of the 4-point female SPEAKON is connected by a flexible, sheathed conductor cable soldered to a contact ring (38); point +2 of the female 4-point SPEAKON is connected by a flexible, sheathed conductor cable soldered to a contact ring (39).
9 red transparent light emitting diodes (D1 to D9) at 5000 milli candela and 20 milliamperes current-limited to approximately 11 milliamperes each by a resistor (R) rated at approximately 460 ohms. These diodes (D1 to D9) are set out and arranged on the surface of the package accommodating the device in order to form three distinctly separate groups (G3, G2, G4). The anode of one LED (D1) is connected by a flexible, sheathed conductor cable soldered to a contact ring (41). The anode of one LED (D2) is connected by a flexible, sheathed conductor cable soldered to a contact ring (42). The anode of one LED (D3) is connected by a flexible, sheathed conductor cable soldered to a contact ring (43). The anode of one LED (D4) is connected by a flexible, sheathed conductor cable soldered to a contact ring (44). The anode of one LED (D5) is connected by a flexible, sheathed conductor cable soldered to a contact ring (45). The anode of one LED (D6) is connected by a flexible, sheathed conductor cable soldered to a contact ring (46). The anode of one LED (D7) is connected by a flexible, sheathed conductor cable soldered to a contact ring (47). The anode of one LED (D8) is connected by a flexible, sheathed conductor cable soldered to a contact ring (48). The anode of one LED (D9) is connected by a flexible, sheathed conductor cable soldered to a contact ring (49).

The cathodes of the LEDs (D1 to D9 and T) are connected by a flexible, sheathed conductor cable soldered to the ground track (PM). A cylinder of flexible material provided with a nut swaged or bonded to either end (EX) is held by a screw against each of the four attaching holes (TF) of the board supporting the printed circuit and its components; the other end (EX) of the cylinder is attached to the package accommodating the device by a screw passing through the bottom of this package. This means of attachment for the component and printed circuit support board therefore has a flexible part (PS) between its ends (EX).

The device according to the invention is more particularly intended for the testing and analysis of cables provided with connectors used for audio and sound applications.

1) A device for testing and analysing cables equipped with connectors characterized in that it incorporates luminous elements (D1 to D9) arranged and organized on the surface to form distinctly separate groups (G) of two (G2), three (G3) or four (G4).

2) A device for testing and analysing cables equipped with connectors characterized in that it incorporates luminous elements (D) each have a light intensity of at least one thousand milli candela for electric consumption of less than 25 milliamperes.

3) A device according to claim 1 or claim 2 characterized in that the luminous elements (D) consist of segments and/or dots.

4) A device according to any one of the previous claims characterized in that the luminous elements (D) are connected to a printed circuit support board and of components made integral with the package accommodating the device by one or several attaching resources comprising a flexible part (PS) between their ends (EX).

5) A device according to any one of the previous claims characterized in that it has a normally-closed pressure pulse switch (I) allowing the conduction of an electrical voltage to the contact pins and points of connectors (ED).

6) A device according to claim 5 characterized in that there is no other surface mounted component placed between the normally-closed pressure pulse switches (I) and one of the edges of the package containing the device.

7) A device according to claim 4 characterized in that the attaching resource for the component supporting board and the circuit having a flexible part (PS) between its ends (EX) has a nut at one end (EX).
